(19) United States
(12) Patent Application Publication
(10) Pub. No.: US 2006/0084283 A1
(43) Pub. Date: Apr. 20, 2006

(54) Low temperature sin deposition methods

(76) Inventors: Ajit P. Paranjpe, Fremont, CA (US); Kangzhan Zhang, Fremont, CA (US); Brendan McDougall, Livermore, CA (US); Wayne Vereb, Sanclemente, CA (US); Michael Patten, Fremont, CA (US); Alan Goldman, Highland Park, NJ (US); Somnath Nag, Saratoga, CA (US)

Correspondence Address: PATTERSON & SHERIDAN, LLP, 3040 POST OAK BOULEVARD, SUITE 1500, HOUSTON, TX, 77056, US

(21) Appl. No.: 10/970,317

(22) Filed: Oct. 20, 2004

(51) Int. Cl. H01L 21/31

(52) U.S. Cl. 438/791; 438/775

(57) ABSTRACT

A silicon nitride layer is deposited on a substrate within a processing region by introducing a silicon containing precursor into the processing region, exhausting gases in the processing region including the silicon containing precursor while uniformly, gradually reducing a pressure of the processing region, introducing a nitrogen containing precursor into the processing region, and exhausting gases in the processing region including the nitrogen containing precursor while uniformly, gradually reducing a pressure of the processing region. During the steps of exhausting, the slope of the pressure decrease with respect to time is substantially constant.

### BACKGROUND OF THE INVENTION

1. Field of the Invention

Embodiments of the present invention generally relate to substrate processing. More particularly, the invention relates to chemical vapor deposition processes.

2. Description of the Related Art

Chemical vapor deposited (CVD) films are used to form layers of materials within integrated circuits. CVD films are used as insulators, diffusion sources, diffusion and implantation masks, spacers, and final passivation layers. The films are often deposited in chambers that are designed with specific heat and mass transfer properties to optimize the deposition of a physically and chemically uniform film across the surface of a substrate. The chambers are often part of a larger integrated tool to manufacture multiple components on the substrate surface. The chambers are designed to process one substrate at a time or to process multiple substrates.

As device geometries shrink to enable faster integrated circuits, it is desirable to reduce thermal budgets of deposited films while satisfying increasing demands for high productivity, novel film properties, and low foreign matter. Historically, CVD was performed at temperatures of 700° C. or higher in a batch furnace where deposition occurs in low pressure conditions over a period of a few hours. Lower thermal budget can be achieved by lowering deposition temperature. Low deposition temperature requires the use of low temperature precursors or reducing deposition time.

Silicon halides have been used as low temperature silicon sources (see, Skordas, et al., Proc. Mat. Res. Soc. Symp. (2000) 606:109-114). In particular, silicon tetraiodide or tetraiodosilane (SiI₄) has been used with ammonia (NH₃) to deposit silicon nitride at temperatures below 500° C. The silicon nitride deposition rate is roughly independent of precursor exposure once a threshold exposure is exceeded. FIG. 1 illustrates how the normalized deposition rate as a function of silicon precursor exposure time reaches a maximum asymptotically and thus, the time for precursor exposure may be estimated. The temperature was 450° C. SiI₄ was the silicon containing precursor with a partial pressure of 0.5 Torr and ammonia was the nitrogen containing precursor.

However, SiI₄ is a solid with low volatility making low temperature silicon nitride deposition process difficult. Also, these films are nitrogen rich, with a silicon to nitrogen content ratio of about 0.66 compared with a silicon to nitrogen content ratio of about 0.75 for stochiometric films. The films also contain about 16 to 20 percent hydrogen. The high hydrogen content of these materials can be detrimental to device performance by enhancing boron diffusion through the gate dielectric for positive channel metal oxide semiconductor (PMOS) devices and by deviating from stoichiometric film wet etch rates. That is, the wet etch rates using HF or hot phosphoric acid for the low temperature SiI₄ film is three to five times higher than the wet etch rates for silicon nitride films deposited using dichlorosilane and ammonia at 750° C. Also, using ammonia as a nitrogen containing precursor with silicon halides for the deposition of silicon nitride films results in the formation of ammonium salts such as NH₄Cl, NH₄BR, NH₄I, and others.

Another method of depositing silicon nitride film at low temperature uses hexachlorodisilane (HCDS) (Si₂Cl₆) with ammonia (see Tanaka, et al., J. Electrochem. Soc. 147: 2284-2289, U.S. Patent Application Publication 2002/0164890, and U.S. Patent Application Publication 2002/0024119). FIG. 2 illustrates how the deposition rate does not asymptote to a constant value for large exposure doses, but monotonically increases without reaching a saturation value even with large exposure doses. This is the gradual decomposition of the surface chemisorbed HCDS when it is exposed to additional HCDS in the gas phase to form a S₁—Cl₂ layer on the surface with the possible creation of SiCl₄. Introducing SiCl₄ with HCDS was found to slightly reduce the decomposition of the HCDS in the chamber. The nitrogen containing precursor for this experiment was ammonia.

When HCDS decomposes, the thickness of the deposited film may not occur uniformly across the substrate. Wafer to wafer film thickness variations may also occur. The film stochiometry is degraded. The films are silicon rich and contain substantial amounts of chlorine. These deviations may lead to electrical leakage in the final product. To prevent HCDS decomposition, limiting the partial pressure and exposure time of HCDS has been tested. U.S. Patent Application 20020164890 describes controlling chamber pressure to 2 Torr and using a large flow rate of carrier gas to reduce the HCDS partial pressure. However, to achieve adequate saturation of the surface for deposition rates exceeding 2 Å per cycle, long exposure times such as 30 seconds are necessary. If the exposure time is reduced, the deposition rate can drop below 1.5 Å per cycle.

Substrate surface saturation with HCDS may also be improved by maintaining convective gas flow across the wafer to distribute reactants evenly. This is described in U.S. Pat. Nos. 5,551,985 and 6,352,593.

An additional problem with low temperature silicon nitride deposition is the condensation of precursors and the reaction byproducts on the chamber surfaces. As these deposits release from the chamber surfaces and become friable, they may contaminate the substrate. Ammonium salt formation is more likely to occur at low temperature silicon nitride deposition because of the evaporation and sublimation temperatures of the salts. For example, NH₄Cl evaporates at 150° C.

Thus, a need exists for low temperature silicon nitride deposition that discourages the formation of ammonium salts and utilizes effective precursors and efficient process conditions.

### SUMMARY OF THE INVENTION

The present invention generally provides a method for depositing a layer comprising silicon and nitrogen on a substrate within a processing region. According to an embodiment of the present invention, the method includes the steps of introducing a silicon containing precursor into the processing region, exhausting gases in the processing region including the silicon containing precursor while uniformly, gradually reducing a pressure of the processing region, introducing a nitrogen containing precursor into the processing region, and exhausting gases in the processing region including the nitrogen containing precursor while uniformly, gradually reducing a pressure of the processing region. According to an aspect of the invention, the slope of the pressure decrease with respect to time during the steps of exhausting is substantially constant.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a chart of the normalized deposition rate as a function of silicon source exposure time (prior art).

FIG. 2 is a chart of the deposition rate as a function of pressure for two temperatures (prior art).

FIG. 3 is a chart of pressure as a function of time.

FIG. 4 is a flow chart of elements for depositing a silicon nitride film.

FIG. 5 is a chart of the deposition rate and WiW non-uniformity as functions of temperature.

FIG. 6 is a chart of the wafer non-uniformity as a function of pressure.

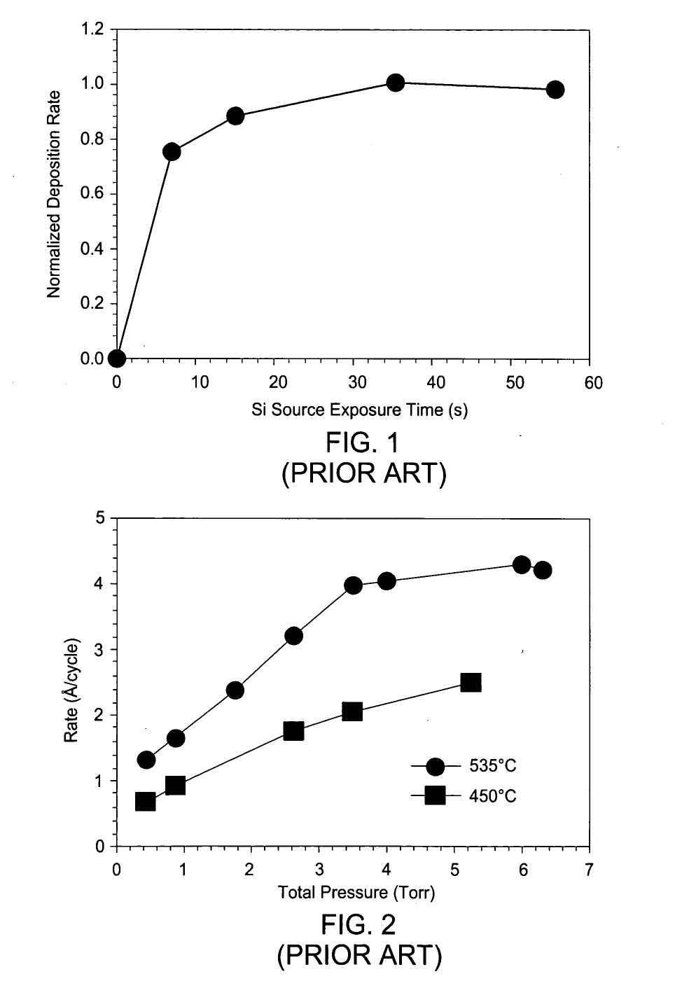

### DETAILED DESCRIPTION

The present invention provides methods and apparatus for substrate processing including low temperature deposition of silicon nitride films. This detailed description will describe silicon containing precursors, nitrogen containing precursors, and other process gases. Next, process conditions will be described. Finally, experimental results and advantages will be presented. This invention may be performed in a FlexStar™ chamber available from Applied Materials, Inc. of Santa Clara, Calif. or any other chamber configured for substrate processing under conditions specified herein. Detailed hardware information may be found in U.S. Pat. No. 6,352,593, U.S. Pat. No. 6,352,594, U.S. patent application Ser. No. 10/216,079, and U.S. patent application Ser. No. 10/342,151 which are incorporated by reference herein. Carrier gases for the introduction of the precursor gases include argon and nitrogen. Purge gases for the purge steps in the process include argon and nitrogen.

Silicon Containing Precursors

Silicon containing precursors for low temperature silicon nitride deposition are hexachlorodisilane and dichlorosiline. The silicon containing precursor may be selected because it is a liquid or solid at room temperature that easily vaporizes or sublimes at preheat temperatures. Other silicon containing precursors include the silicon halides, such as SiI₄, SiBr₄, SiH₂I₂, SiH₂Br₂, SiCl₄, Si₂H₂Cl₂, SiHCl₃, Si₂Cl₆, and more generally, SiXₙY₄₋ₙ or Si₂XₙY₆₋ₙ, where X is hydrogen or an organic ligand and Y is a halogen such as Cl, Br, F, or 1. Higher order halosilanes are also possible, but typically precursor volatility decreases and thermal stability decreases as the number of silicon atoms in the molecule increases. Organic components can be selected for their size, thermal stability, or other properties and include any straight or branched alkyl group such as methyl, ethyl, propyl, butyl, pentyl, hexyl, heptyl, octyl, nonanyl, decyl, undecyl, dodecyl, substituted alkyl groups, and the isomers thereof such as isopropyl, isobutyl, sec-butyl, tert-butyl, isopentane, isohexane, etc. Aryl groups may also be selected and include pheyl and naphthyl. Allyl groups and substituted allyl groups may be selected. Silicon containing precursors that are desirable for low temperature deposition applications include disilane, silane, trichlorosilane, tetrachlorosilane, and bis(tertiarybutylamino)silane. SiH₂I₂ may also be desirable as a precursor because it is has an very exergonic and exothermic reaction with nitrogen containing precursors compared to other precursors.

Nitrogen Containing Precursors

Ammonia is the most common source of nitrogen for low temperature silicon nitride deposition. Alkyl amines such may be selected. Alternatives include dialkylamines and trialkylamines. Specific precursors include trimethylamine, t-butylamine, diallylamine, methylamine, ethylamine, propylamine, butylamine, allylamine, cyclopropylamine, and analogous alkylamines. Hydrazine, hydrazine based derivatives and azides such as alkyl azides, ammonium azide, and others may also be selected. Alternatively, atomic nitrogen can be employed. Atomic nitrogen can be formed from diatomic nitrogen gas in plasma. The plasma can be formed in a reactor separate from the deposition reactor and transported to the deposition reactor via electric or magnetic fields.

The silicon or nitrogen containing precursor may also be selected based on what type of undesirable deposit is formed along the surfaces of the processing region. Byproduct residue with low melting points is easier to volatilize and exhaust from the chamber than those byproduct residues that have high melting points.

Process Conditions for Deposition

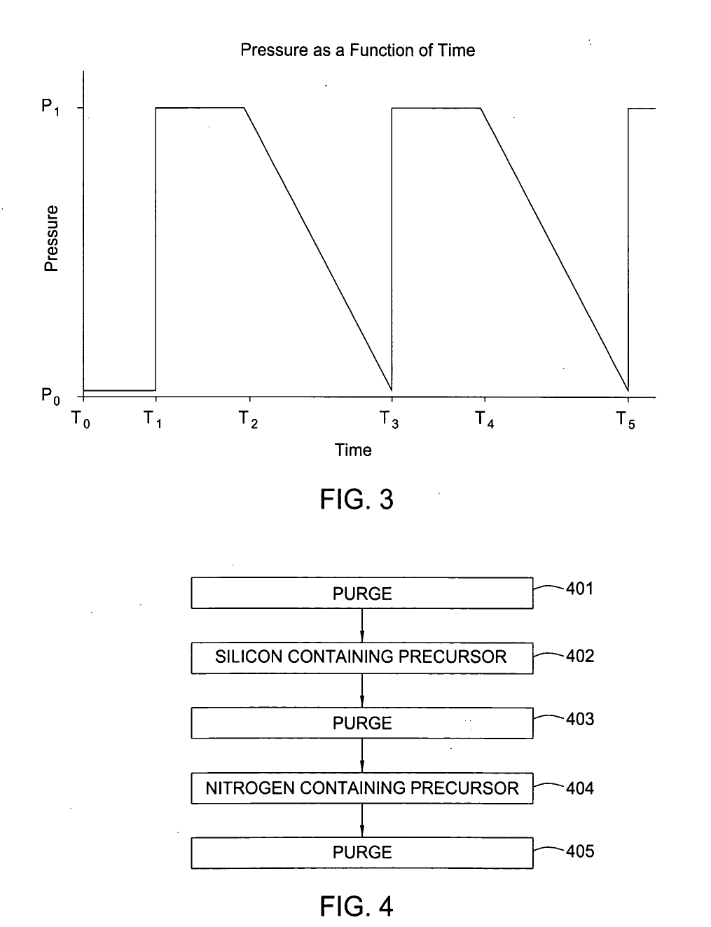

FIGS. 3 and 4 concurrently illustrate how the chamber pressure may be manipulated while introducing and exhausting the precursor, carrier, and purge gases into and out of the chamber. At time to which is the purge step 401, the chamber pressure is at Pₒ, the lowest pressure of the chamber during deposition. At time t₁ which is silicon containing precursor step 402, the silicon containing precursor and optional carrier gas are introduced into the chamber and the chamber pressure rises quickly to P₁. The supply of the silicon containing precursor and optional carrier gas continues at chamber pressure of P₁ until t₂. During the purge step 403 which occurs from t₂ to t₃, a gradual decrease in chamber pressure to Pₒ is achieved by controlling the decrease in the precursor gas and optional gas introduced into the chamber and controlling the purge gas introduced into the chamber, and controlling the opening of the exhaust valve. At time t₃ which is nitrogen containing precursor step 404, the nitrogen containing precursor and optional carrier gas are introduced into the chamber and the chamber pressure rises quickly to P₁. The supply of the nitrogen containing precursor and optional carrier gas continues at chamber pressure of P₁ until t₄. During the purge step 405 which occurs from t₄ to t₅, a gradual decrease in chamber pressure to Pₒ is achieved by controlling the decrease in the precursor gas and optional gas introduced into the chamber and controlling the purge gas introduced into the chamber, and controlling the opening of the exhaust valve. The slope of the pressure decrease with respect to time is substantially constant during the purge steps 403 and 405. The slopes for steps 403 and 405 may be similar or different depending on the selection of the precursors, the temperature of the substrate support, or other design conditions.

The initial high concentration of precursors upon introduction to the processing region allows a rapid saturation of the substrate surface including the open sites on the substrate surface. If the high concentration of precursor is left in the chamber for too long, more than one layer of the precursor constituent will adhere to the surface of the substrate. For example, if too much silicon containing precursor remains along the surface of the substrate after it is purged from the system, the resulting film will have an unacceptably high silicon concentration. The controlled, gradual reduction in processing region pressure helps maintain an even distribution of chemicals along the substrate surface while forcing the extraneous precursor and carrier gases out of the region while simultaneously purging the system with additional purge gas such as nitrogen or argon. The controlled, gradual reduction in the processing region pressure also prevents the temperature decrease that is common with a rapid decrease in pressure.

The precursor steps 402 and 404 include the introduction of the precursor into the chamber. The precursor steps may also include introduction of carrier gases, such as nitrogen or argon. Further, a fixed volume of precursor may be heated in a preheat region, and introduced into the processing region to provide a evenly distributed, saturated layer of the precursor gas along the surface of the substrate.

The time for the introduction of precursor gases and for purging the gases may be selected based on a variety of factors. The substrate support may be heated to a temperature that requires precursor exposure time tailored to prevent chemical deposition along the chamber surfaces. The processing region pressure at the introduction of the gases and at the end of the purge may influence time selection. The precursors need various amounts of time to fully chemisorb along the surface of the substrate but not overly coat the surface with an excess of chemicals that could distort the chemical composition of the resulting film. The chemical properties of the precursors, such as their chemical mass, heat of formation, or other properties may influence how much time is needed to move the chemicals through the system or how long the chemical reaction along the surface of the substrate may require. The chemical properties of the deposits along the surfaces of the chamber may require additional time to purge the system. In the illustrated embodiment, the time period for the introduction of precursor and optional carrier gases ranges from 1 to 5 seconds and the time period for the purge steps ranges from 2 to 10 seconds.

HCDS or DCS are the preferred silicon containing precursors. The partial pressure HCDS is limited by the byproduct formation and the cost of the precursor. The preferred mole fraction of the introduction of the precursor 0.05 to 0.3. Ammonia is the preferred nitrogen containing precursor which also has a preferred inlet gas mole fraction of 0.05 to 0.3.

The pressure of the processing region may be controlled by manipulating the process hardware such as inlet and exhaust valves under the control of software. Pressure of the system as illustrated by FIG. 3 may range from 0.1 Torr to 30 Torr for this process. Purge pressure in the processing region of a chamber at its lowest point in the deposition process is about 0.2 to 2 Torr while the precursor and carrier gases may be introduced into the deposition chamber at about 2 to about 10 Torr. The temperature of the substrate support may be adjusted to about 400 to 650° C.

The introduction of gases into the chamber may include preheating the precursors and/or carrier gas, especially when precursors that are unlikely to be gas at room temperature are selected for the process. The gases may be preheated to about 100 to 250° C. to achieve sufficient vapor pressure and vaporization rate for delivery to a processing region. Heating SiI₄ above about 180° C. may be needed. Preheating the precursor delivery system helps avoid condensation of the precursor in the delivery line, the processing region, and the exhaust assembly of a chamber.

Process for Reducing Ammonium Salt Formation

Five mechanisms may be employed to reduce ammonium salt formation and contamination of the processing region. Generally, the mechanisms minimize the formation of ammonium salts by removing hydrogen halogen compounds from the processing region or removing the salts after formation by contacting the salts with a gaseous alkene or alkyne species.

First, an HY acceptor such as acetylene or ethylene can be employed as an additive. Including an HY acceptor in deposition precursor mixtures allows the salts to be efficiently removed from the reactor and can facilitate the removal of halogen atoms dissociated from the silicon or nitrogen containing precursors. Other HY acceptor additives include alkenes which can be halogenated or unhalogenated, strained ring systems such as norborene and methylene cyclopentene, and silyl hydrides such as SiH₄. Using organic additives may also be a benefit to the deposition process because the additives may be selected to tailor carbon addition to the film. Controlling the carbon addition to the film is desirable because tailored carbon content reduces the wet etch rate, improves dry etch selectivity for SiO₂, lowers the dielectric constant and refractive index, provides improved insulation characteristics, and may also reduce electrical leakage. High corner etch selectivity may also be obtained with tailored carbon addition.

Second, silyl hydride additives such as silane may be employed as HI acceptors. Including HI acceptors reduces the negative effects of ammonium salt in the processing region by trapping out the NH₄₁ that does form.

Third, compounds that act as both silicon containing precursors and HI acceptors may be employed to both provide silicon to the process and to effectively remove the salts from the chamber. Acceptable silicon containing precursors include those with formulas SiXₙY₄₋ₙ or Si₂XₙY₆₋ₙ.

Fourth, a nitrogen source other than ammonia as the nitrogen containing precursor may be employed, thus eliminating a raw material for the formation of the ammonium salts. For example, when an alkyl amine is employed as a nitrogen source, less HY is produced than when ammonia is employed. Tralkyl amines are thermodynamically more desirable and produce no HY when used as a nitrogen containing precursor.

Finally, an HY accepting moiety such as a cyclopropyl group or an allyl group can be incorporated into a nitrogen source such as an amine to make a resulting bifunctional compound such as cyclopropylamine or allylamine. This method reduces the need to add a third component to the precursor gas inlet. It also increases the likelihood that an HI acceptor combines with an HY acceptor. This method also may be especially desirable at temperatures below 500° C.

These five methods may be individually employed or combined in any fashion to help reduce ammonium salt formation.

Experimental Results

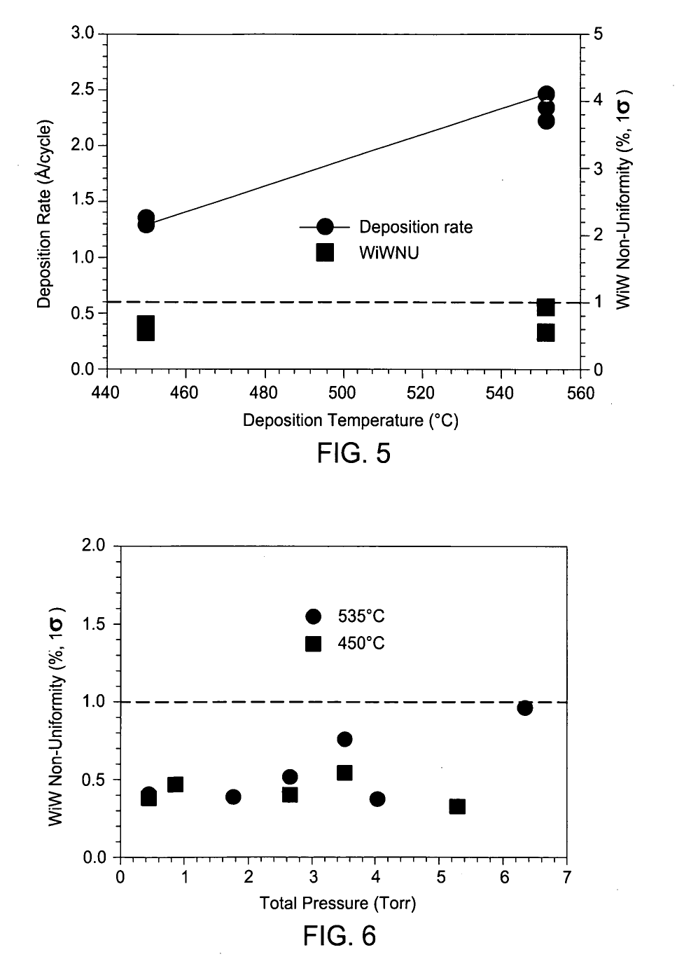

Modifying the traditional purge system to have a gradual and uniform reduction in processing region pressure as described in FIGS. 3 and 4 results in a higher level of precursor surface saturation without partial decomposition of the precursor. FIG. 5 illustrates how the wafer to wafer nonuniformity (in percent) and the deposition rate (in Å/cycle) are related to the temperature of deposition from 450 to 550° C. using HCDS and ammonia as the precursors. FIG. 6 illustrates how pressure from 0.2 to 7 Torr during the introduction of the precursor gases effects the wafer to wafer nonuniformity. The films were deposited using HCDS and ammonia at 550° C. Fourier transform infrared spectroscopy analysis revealed that the film was Si₃N₄. The step coverage for the film exceeded 95 percent. The process also yielded chlorine content of less than 1 percent. Deposition rates increased to 2 Å/cycle at 590° C. and decreased to 0.8 Å/cycle at 470° C. Boron diffusion through the resulting film is also reduced at lower temperatures. Table 1 below summarizes additional experimental results at 550° C.

TABLE 1
Testing results for silicon nitride film deposited at 550° C.

| Parameter | Value | Comment |
|---|---|---|
| Deposition rate | 1.5-1.6 A/cycle | Below saturation value |
| WiWNU | <±1.5% | R/2M |
| Refractive index | 1.99 | >300 Å film |
| Stoichiometry | Si:N˜0.74 | Stoichiometric |
| Impurities | H˜8% Cl˜0.9% | Atomic % |
| Surface roughness | Ra˜3.7 Å | ˜417 Å film |
| Wet etch rates | 31.5 Å/min | 100:1 HF, 2 min. |
| | 222 Å/min | Hot H₃PO₄, 0.5 min. |
| Shrinkage | ˜4.3% | 850° C., 60 min N₂ anneal |
| Stress | 450 MPa tensile | 1620 MPa after anneal |
| Step coverage | ˜100% | 40:1 AR deep trench |
| Microloading | 0-5% | Limited by SEM resolution |
| Metal contamination | TXRF detection limits | Including Ti |
| In-film Particles | <50 (>0.2 μm) | 100 Å film, SP-1 |

Introducing a carrier gas or an additive such as hydrogen or disilane also modifies the resulting film properties. Table 2 illustrates the observed deposition rates, refractive index, silicon to nitrogen ratio, and hydrogen percentage observed in films created by using different split recipes. By utilizing a carrier gas that does not comprise nitrogen or a carrier gas and comprises an additive, the hydrogen content and silicon to nitrogen ratio of the film can be improved.

TABLE 2
Properties of films deposited under baseline
conditions and with additives.

| | Rate | | | [H] |
|---|---|---|---|---|
| Split | Å/min | R.I. | Si:N | At. % |
| Baseline (w/N₂) | 14.5 | 1.800 | 0.65 | 20.2 |
| Baseline (w/Ar) | 13.5 | 1.799 | 0.72 | 20.5 |
| Low pressure (0.5 Torr) | 6.76 | 1.811 | 0.65 | 19.1 |
| NH₃:Si source˜20:1 | 17.9 | 1.807 | 0.65 | 19.7 |
| NH₃:Si source˜4:1 | 12.0 | 1.795 | 0.72 | 20.1 |
| Hydrogen Additive | 14.3 | 1.804 | 0.65 | 19.4 |
| Disilane Additive | 20.6 | 2.386 | 1.0 | 11.3 |

There are a variety of ways to control the addition of carbon. In Table 3, A is the silicon precursor (HCDS), B is the nitrogen precursor (ammonia), and C is the additive (t-butylamine).

TABLE 3
Deposition rates, refractive index, and wet
etch rate for varied deposition processes.

| | Rate | Refractive | WER |
|---|---|---|---|
| Recipe | Å/cycle | Index | Å/min |
| A → B | 1.9 | 1.95 | 13 |
| A → C | 1.0 | 1.93 | 1 |
| A → B → C | 1.65 | 1.93 | 3 |
| A → C → B | 1.85 | 1.94 | 4 |
| A → B → A → C | 1.70 | 1.92 | 4 |
| A → 33% B + 67% C | 1.80 | 1.93 | 4 |
| A → 67% B + 33% C | 2.0 | 1.94 | 9 |
| A → 50% B + 50% C₂H₄ | 1.9 | 2.0 | 7 |

Films deposited with the A→C→A→C sequence contain up to 20 percent carbon while the A→B→A→B sequence film contained no carbon. Other recipes led to intermediate values of carbon in the film. If C₂H₄ is substituted for t-butylamine in the sequence A→50% B+50% C, the wet etch rate of the film is reduced appreciably while the deposition rate and refractive index are almost unaffected. In addition, the carbon content is at detection limits (less than 1 atomic percentage).

Introducing carbon in controlled amounts improves wet etch rates in 100:1 HF by a factor of 1.5 to 10. The reduction in dry etch rates with the addition of carbon were by a factor of 1.25 to 1.5. This improved wet etch rate was observed by using ethylene, t-butylamine and diallylamine as HY acceptors in conjunction with Si₂CL₆ and ammonia.

Introducing SiCl₄ with HCDS was found to reduce the likelihood of decomposition of HCDS to form SiCl₂.

The precursors described herein may also be employed in low temperature deposition of silicon oxides. The process can employ O₂, O₃, H₂O, H₂O₂, N₂O, or Ar and O₂ with remote plasma as the oxidant. The precursors can also be employed in the low temperature deposition of oxynitrides wherein N₂O₂ is employed as both a nitrogen and an oxygen source.

While the foregoing is directed to embodiments of the present invention, other and further embodiments of the invention may be devised without departing from the basic scope thereof, and the scope thereof is determined by the claims that follow.

1. A method for depositing a layer comprising silicon and nitrogen on a substrate within a processing region, comprising:
introducing a silicon containing precursor into the processing region;
exhausting gases in the processing region including the silicon containing precursor while uniformly, gradually reducing a pressure of the processing region;
introducing a nitrogen containing precursor into the processing region; and
exhausting gases in the processing region including the nitrogen containing precursor while uniformly, gradually reducing a pressure of the processing region.

2. The method of claim 1, further comprising maintaining a support for the substrate at a temperature of 400 to 650° C.

3. The method of claim 1, wherein the pressure of the processing region is 0.2 to 10 Torr.

4. The method of claim 1, wherein a slope of pressure decrease with respect to time during each step of exhausting is substantially constant.

5. The method of claim 4, wherein the slopes of the pressure decrease with respect to time during the steps of exhausting are substantially the same.

6. The method of claim 4, wherein a time period for introducing the silicon containing precursor and a time period for introducing the nitrogen containing precursor is 1 to 5 seconds.

7. The method of claim 4, wherein a time period for exhausting gases in the processing region including the silicon containing precursor and the nitrogen containing precursor is 2 to 20 seconds.

8. The method of claim 1, wherein a pressure in the processing region while introducing the silicon containing precursor is 0.2 to 10 Torr and a pressure in the processing region while introducing the nitrogen containing precursor is 0.2 to 10 Torr.

9. The method of claim 1, wherein a pressure in the processing region before introducing the silicon containing precursor is 0.2 Torr and a pressure in the processing region before introducing the nitrogen containing precursor is 0.2 Torr.

10. The method of claim 1, wherein the nitrogen containing precursor is selected from the group comprising ammonia, trimethylamine, t-butylamine, diallylamine, methylamine, ethylamine, propylamine, butylamine, allylamine, and cyclopropylamine.

11. The method of claim 1, wherein the silicon containing precursor is selected from the group comprising disilane, silane, trichlorosilane, tetrachlorosilane, and bis(tertiarybutylamino)silane.

12. A method for depositing a layer comprising silicon and nitrogen on a substrate within a processing region, comprising:
preheating a silicon containing precursor and a nitrogen containing precursor;
introducing a silicon containing precursor into the processing region;
exhausting gases in the processing region including the silicon containing precursor while uniformly, gradually reducing a pressure of the processing region;
introducing a nitrogen containing precursor into the processing region; and
exhausting gases in the processing region including the nitrogen containing precursor while uniformly, gradually reducing a pressure of the processing region.

13. The method of claim 12, wherein the silicon containing precursor and the nitrogen containing precursor are preheated to 100 to 250° C.

14. The method of claim 12, wherein the pressure of the processing region is reduced during the steps of exhausting by controlling an amount of purge gas introduced into the processing region and by controlling an exhaust valve in communication with the processing region.

15. The method of claim 12, wherein the nitrogen containing precursor is selected from the group comprising ammonia, trimethylamine, t-butylamine, diallylamine, methylamine, ethylamine, propylamine, butylamine, allylamine, and cyclopropylamine and the silicon containing precursor is selected from the group comprising disilane, silane, trichlorosilane, tetrachlorosilane, and bis(tertiarybutylamino)silane.

16. The method of claim 12, wherein a support for the substrate in the processing region is maintained at a temperature of 400 to 650° C.

17. The method of claim 12, wherein a pressure of the processing region is 0.2 to 10 Torr.

18. A method for depositing a layer comprising silicon and nitrogen on a substrate in a processing region, comprising:
introducing a silicon containing precursor into the processing region;
exhausting gases in the processing region including the silicon containing precursor while reducing a pressure of the processing region such that a slope of pressure decrease with respect to time is substantially constant;
introducing a nitrogen containing precursor into the processing region; and
exhausting gases in the processing region including the nitrogen containing precursor while reducing a pressure of the processing region such that a slope of pressure decrease with respect to time is substantially constant.

19. The method of claim 18, wherein a time period for introducing the silicon and nitrogen containing precursors is 1-5 seconds and a time period for exhausting gases including the silicon and nitrogen containing precursors is 2-20 seconds.

20. The method of claim 18, wherein a pressure of the processing region is 0.2 to 10 Torr.
